(19) United States
(12) Patent Application Publication
(10) Pub. No.: US 2024/0332872 A1
(43) Pub. Date: Oct. 3, 2024

(54) PLUG HOLDING DEVICE FOR HOLDING A CONNECTION PLUG, HOUSING OF AN AXLE DEVICE AND SYSTEM FOR FASTENING A CONNECTION PLUG

(71) Applicant: Schaeffler Technologies AG & Co. KG, Herzogenaurach (DE)

(72) Inventors: Robert Schieck, Nürnberg (DE); Christoph Protze, Baiersdorf (DE); Jochen Lüdemann, Chemnitz (DE)

(73) Assignee: Schaeffler Technologies AG & Co. KG, Herzogenaurach (DE)

(21) Appl. No.: 18/604,609

(22) Filed: Mar. 14, 2024

(30) Foreign Application Priority Data
Mar. 27, 2023 (DE) 10 2023 107 603.5

(51) Int. Cl. H01R 13/73; B60B 35/16; B60R 16/03

(52) U.S. Cl. CPC H01R 13/73; B60B 35/16; B60R 16/03; H01R 2201/26

(57) ABSTRACT

A plug holding device for holding a connection plug of an electrical plug connection on a housing section of a housing of an axle device includes a holder configured to hold the plug holding device on the housing section of the housing of the axle device and to hold the connection plug of the electrical plug connection. The plug holding device further includes a positioner configured to position the connection plug of the electrical plug connection relative to the plug holding device. The holder includes a feed-through configured to receive a male section of the connection plug of the electrical plug connection.

### CROSS-REFERENCE TO RELATED APPLICATIONS

This application claims priority to German Appln. No. DE102023107603.5, filed Mar. 27, 2023, the entire disclosure of which is incorporated by reference herein.

### TECHNICAL FIELD

The present disclosure relates to a plug holding device for holding a connection plug of an electrical plug connection on a housing section of a housing of an axle device. The present disclosure further relates to a housing of an axle device and a system for fastening a connection plug of an electrical plug connection to a housing section of a housing of an axle device.

### BACKGROUND

According to FIG. 1, a plug holding device 100 for holding a connection plug 180 of an electrical plug connection on a housing of an axle device is known from the prior art, for example. Here, the plug holding device 100 is fastened to a housing 150 on the one hand and holds a connection plug 80 in position on the other.

Strictly speaking, the plug holding device 100 has a holder for holding the plug holding device 100 on the housing 150 and for holding a connection plug 80 of an electrical plug connection. Furthermore, the plug holding device 100 comprises a positioner for positioning a connection plug 80 of an electrical plug connection relative to the plug holding device 100.

Due to the boundary conditions of the housing 150 or the special attachment location of the plug holding device 100 within an axle device, the connection plug 80 is generally not accessible. A controlled insertion of the electrical plug connection or the connection plug 80 into a socket is therefore impossible, so that only a blind assembly remains feasible.

To allow for a blind assembly with differently formed housings of axle devices for the connection plug 80, a plug holding device 100 is designed and adapted separately for each axle device so that the task of plug positioning and fastening during the insertion process can be achieved by way of a blind assembly.

Individually designing a plug holding device for the different housings of axle devices is not only time-consuming but also cost-intensive.

### SUMMARY

The present disclosure provides, according to an exemplary embodiment, a plug holding device for holding a connection plug of an electrical plug connection on a housing section of a housing of an axle device in such a way that a blind assembly and/or a cost-effective and material-saving production of an electrical plug connection can be ensured.

The present disclosure provides a plug holding device for holding a connection plug of an electrical plug connection on a housing section of a housing of an axle device. The axle device can be an axle device for a motor vehicle. The axle device can also be, for example, an electric axle for a motor vehicle or an E-axle for a motor vehicle.

The plug holding device has a holder configured to hold the plug holding device on the housing section of the housing of the axle device and to hold the connection plug of the electrical plug connection.

Furthermore, the plug holding device comprises a positioner configured to position the connection plug of the electrical plug connection relative to the plug holding device.

The holder has a feed-through configured to receive a male section of the connection plug of the electrical plug connection. This design allows the connection plug of the electrical plug connection to be positioned between the plug holding device and the housing or the housing section of the housing.

Furthermore, the holder, or at least a first holding section of the holder, can be configured and designed such that the connection plug of the electrical plug connection can be arranged so as to be displaceable on the housing section of the housing of the axle device. The displaceability of the connection plug can, for example, be ensured in a first plane orientation or the connection plug can be arranged so as to be displaceable in the first plane orientation. Furthermore, the displaceability allows for a simple blind assembly, as the connection plug has a range of movement that facilitates insertion into a correspondingly designed socket during blind assembly.

In addition, the holder can have at least one first holding section, via which the connection plug of the electrical plug connection can be arranged, for example directly, on the housing section of the housing of the axle device. In this regard, the at least one first holding section can at least partially delimit the feed-through or adjoin the feed-through. This makes it possible to introduce supporting forces, for example directly or immediately, when the connection plug is plugged into the housing section of the housing of the axle device, without another element or component or another device being arranged in between.

Furthermore, the at least one first holding section can have a flat contact surface which can be arranged in contact with a holding region of the connection plug of the electrical plug connection in order to ensure that the holding region of the connection plug bears flat against the plug holding device. This allows for the distribution of pressure.

In this regard, the at least one first holding section can be aligned in the first plane orientation.

The term “plane orientation” can refer to the alignment or orientation of a plane in a geometric and/or mathematical sense. Furthermore, the wording “aligned in a first plane orientation” can be understood to mean that a section or a region or a surface or a part or component or an element is oriented parallel to an ideally formed plane (in the geometric and/or mathematical sense). In the present description, the term “parallel” shall not be understood as a state as known from mathematics, for example. In this context, not only shape-related tolerances, but also positional tolerances with deviations of 3 to 10 percent of a section or a region or a surface or a part or component or an element in relation to an ideal or mathematically formed plane can be considered acceptable.

In addition, the holder can have at least one second holding section, via which the plug holding device can be fastened to the housing section of the housing of the axle device. This allows the plug holding device to be attached to the housing section.

The at least one second holding section can have at least one securing device which makes it more difficult to remove the plug holding device from the housing section of the housing of the axle device. The securing device can be designed as a barb.

Furthermore, the at least one second holding section can have two securing devices arranged next to one another. This can serve to increase the securing effect.

The at least one securing device can also be designed as a cantilever, the free end of which is oriented in the direction of the feed-through.

In addition, at least two securing devices can be arranged opposite or symmetrically with respect to the feed-through. This improves the hold of the plug holding device on the housing section.

The at least one second holding section can also be aligned in a second plane orientation.

Furthermore, the plug holding device can be U-shaped or have a U-shape in a cross-section that is aligned in a third plane orientation, for example. This shape makes it easier to receive the housing section of the housing of the axle device.

A first and second leg of the U-shape, which can be aligned in the same direction, can each be formed by a second holding section of the holder.

A third leg of the U-shape, which can act as a connection between the first and second legs, can be formed by two first holding sections of the holder and the feed-through between the two first holding sections.

Furthermore, the positioner can have at least one first positioning element, via which the relative position of the connection plug of the electrical plug connection to the plug holding device can be predetermined in the first plane orientation. This means that the movement of the connection plug of the electrical plug connection can be limited relative to the plug holding device.

In addition, the at least one first positioning element can be arranged on the feed-through and/or adjoin the feed-through.

The at least one first positioning element can also be arranged on a stiffener of the plug holding device or on a stiffening section of a stiffener of the plug holding device.

Two first positioning elements can be arranged opposite and on the feed-through in order to position the connection plug of the electrical plug connection relative to the plug holding device.

Two first positioning elements can also be spaced apart from the holder, for example from at least one first holding section of the holder. This makes it easier to act on the connection plug.

Furthermore, the positioner can have at least one second positioning element, via which the relative position of the connection plug of the electrical plug connection to the plug holding device can be predetermined in the first plane orientation. In this way, the movement of the connection plug of the electrical plug connection can be limited relative to the plug holding device.

The at least one second positioning element can be arranged at a transition between the first and a second holding section of the holder.

Furthermore, it is possible that the at least one second positioning element is formed integrally or in one piece with the first or with a second holding section of the holder. This simplifies production.

The at least one second positioning element can also be L-shaped.

Furthermore, the plug holding device can have the stiffener which connects the first and second holding section of the holder to one another and/or mechanically stiffens them.

The stiffener can have a first and/or second stiffening section that is designed to be flat. The first and/or second stiffening section can be aligned in the third plane orientation.

Furthermore, the stiffener or its first and/or second stiffening section can form at least one contact nose, via which the stiffener bears against at least one stop surface of a contact part of an attachment region of the housing section of the housing of the axle device.

In addition, the stiffener or its first and/or second stiffening section can at least partially delimit the feed-through or adjoin the feed-through.

The plug holding device can, for example, be made of sheet metal, plastic or a composite material.

The present disclosure further provides a housing of an axle device. The axle device can be an axle device for a motor vehicle. The axle device can also be, for example, an electric axle for a motor vehicle or an E-axle for a motor vehicle.

Reference is explicitly made to the fact that the features of the plug holding device, as mentioned above, can be used individually or in combination with one another in the housing.

In other words, the features mentioned above relating to the plug holding device can also be combined with further features mentioned below. This also applies vice versa.

As such, the housing of the axle device has a housing wall for delimiting an interior of the housing from an exterior of the housing.

Furthermore, the housing comprises a housing section for the attachment of the plug holding device for holding the connection plug of the electrical plug connection.

In this regard, the housing section protrudes from the housing wall towards the interior of the housing.

In addition, the housing section comprises at least one connector for correctly attaching the connection plug of the electrical plug connection. The at least one connector can utilize the so-called “poka-yoke” principle. In this way, incorrect attachment of the connection plug to the housing section can be prevented.

Furthermore, the housing section can have an attachment region for the plug holding device for holding the connection plug of the electrical plug connection.

The attachment region can have a first and a second contact part for the plug holding device for holding the connection plug of the electrical plug connection. The first and second contact parts can be spaced apart from one another. This serves to increase mechanical stability and simultaneously save material.

In this regard, the first contact part can have the at least one connector.

The second contact part can have a stop for restricting the movement of the connection plug of the electrical plug connection in a first plane orientation. In this way, pre-positioning can be achieved prior to blind assembly.

Furthermore, the first and second contact parts can each have a contact surface that is aligned in the first plane orientation.

In addition, the at least one connector and/or the stop for restricting movement can be arranged on or at the contact surface.

The attachment region, or the first and second contact parts of which, can be geometrically designed in such a way that it/they can be received and/or surrounded by the plug holding device for holding the connection plug of the electrical plug connection. This allows for the assembly of different axle devices to be standardized and simplified, as the housing section and the plug holding device can be adapted to one another, akin to the “lock-and-key” principle.

The first and/or second contact part can have at least one stop surface for a positioner of the plug holding device for holding the connection plug of the electrical plug connection. In this regard, the at least one stop surface can be aligned in a second plane orientation.

Furthermore, the at least one stop surface and the contact surface can be oriented perpendicular to one another or enclose an angle of between 80 and 100 degrees with one another.

In addition, the housing section can have a spacing region for spacing apart the attachment region of the housing section from the housing wall. This means that the distance of the plug holding device attached to the housing section can be reduced/increased or, generally, adjusted.

The present disclosure further provides a system for fastening a connection plug of an electrical plug connection to a housing section of a housing of an axle device. The axle device can be an axle device for a motor vehicle. The axle device can also be, for example, an electric axle for a motor vehicle or an E-axle for a motor vehicle.

The housing section can be formed integrally or in one piece.

Reference is explicitly made to the fact that the features of the plug holding device, as mentioned above, can be used individually or in combination with one another in the system.

The features of the housing, as mentioned above, can also be used individually or in combination with one another in the system.

In other words, the features mentioned above concerning the plug holding device and/or the features mentioned above concerning the housing may also be combined here with additional features mentioned below.

The system for fastening the connection plug of the electrical plug connection to the housing section of the housing of the axle device comprises the plug holding device, as mentioned above, for holding the connection plug of the electrical plug connection to the housing section of the housing of the axle device.

The system further comprises the housing of the axle device, as mentioned above.

The system can be configured and designed such that the connection plug of the electrical plug connection, or at least one holding region of which, is arranged so as to be displaceable between the housing section of the housing of the axle device and at least a first holding section of the holder of the plug holding device, for example, can be arranged so as to be displaceable in a first plane orientation. This allows a connection plug to move relative to the housing and the plug holding device, thus facilitating a blind assembly.

The system can also be configured and designed such that the connection plug of the electrical plug connection, or at least one holding region of which, can be arranged so as to be displaceable between a contact surface of a first and/or a second contact part of an attachment region of the housing section and at least one first holding section of the holder of the plug holding device, for example, can be arranged so as to be displaceable in a first plane orientation. This also allows the connection plug to move relative to the housing and the plug holding device, thus facilitating a blind assembly.

Furthermore, the system can comprise the connection plug of the electrical plug connection, which has a male section and at least one holding region.

In this regard, the male section can be arranged in the feed-through of the holder of the plug holding device.

The at least one holding region can also be arranged between at least one first holding section of the holder or a flat contact surface of at least one first holding section of the holder and the contact surface of the first and/or second contact part of the attachment region of the housing section of the housing. Thus, the connection plug can be arranged, for example so as to be movable, between the housing and the plug holding device.

Finally, it should be mentioned that the first plane orientation, the second plane orientation and the third plane orientation can be aligned perpendicular to one another.

Furthermore, the present disclosure can offer the advantages of cost savings due to the use of a single plug holding device, which is always of the same design. This plug holding device can therefore be used in multiple projects, reducing development costs and component costs.

The combination of plug holding device and housing can facilitate the blind assembly of a connection plug in the corresponding counterpart. This simplifies the assembly of an axle device and thus reduces costs.

### BRIEF DESCRIPTION OF THE DRAWINGS

The present disclosure will be explained in more detail below using an exemplary embodiment in conjunction with associated drawings. In the schematic drawings:

FIG. 1 shows a spatial view of a housing with a plug holding device according to the prior art;

FIG. 2 shows a spatial view of a system with a plug holding device and a housing;

FIG. 3 shows only the housing from FIG. 2;

FIG. 4 shows a plan view of the plug holding device on the housing from FIG. 2;

FIG. 5 shows a sectional view of the plug holding device on the housing from FIG. 4 along line A-A;

FIG. 6 shows a side view of the plug holding device on the housing from FIG. 4; and

FIG. 7 shows a further spatial view of the plug holding device on the housing from FIG. 2.

### DETAILED DESCRIPTION

In the description below, the same reference signs are used for the same components.

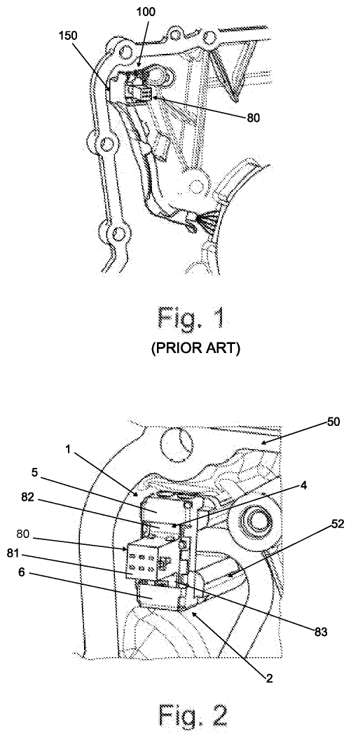

FIG. 1 shows a spatial view of a housing 150 with a plug holding device 100 from the prior art, which has already been discussed at the outset of this description, so that at this point reference is only made to the explanations provided there.

FIG. 2 shows a spatial view of a system with a plug holding device 1 and a housing 50. More specifically, FIG. 2 shows a system for fastening a connection plug 80 of an electrical plug connection to a housing section 52 of a housing 50 of an axle device.

The system comprises the plug holding device 1 for holding the connection plug 80 of the electrical plug connection on the housing section 52 of the housing 50 of the axle device and the housing 50 of the axle device.

The system is configured and designed such that the connection plug 80 of the electrical plug connection or holding regions 82, 83 of which is/are arranged so as to be displaceable between the housing section 52 of the housing 50 of the axle device and first holding sections 5, 6 of a holder 2 of the plug holding device 1, and can, specifically, be arranged so as to be displaceable in a first plane orientation X-Y. This allows the connection plug 80 to move relative to the housing 50 and the plug holding device 1, thus facilitating a blind assembly.

As already explained, the system as such has the connection plug 80 of the electrical plug connection, which has a male section 81 and the two holding regions 82, 83. The male section 81 is arranged in a feed-through 4 of the holder 2 of the plug holding device 1. This design allows the connection plug 80 to be positioned between the plug holding device 1 and the housing 50, or a housing section 52 of a housing 50.

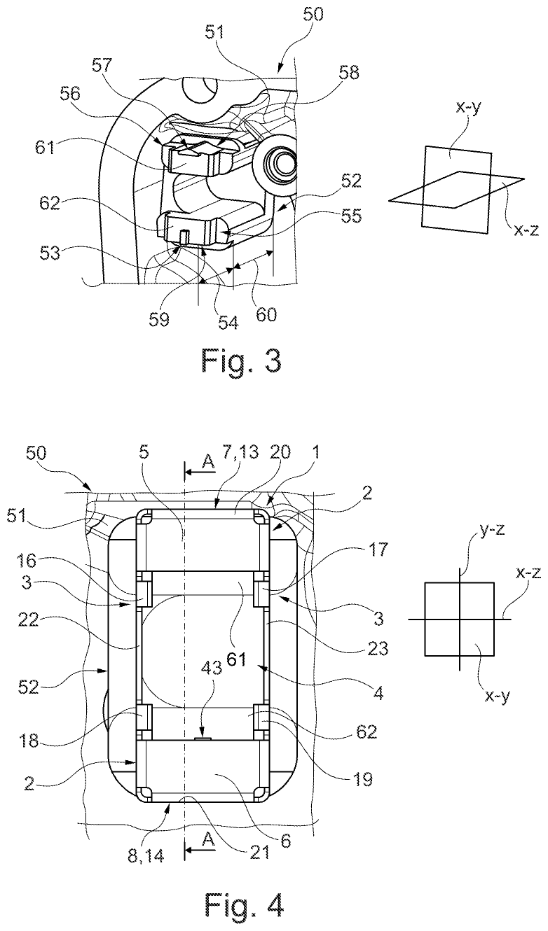

In this regard, the two holding regions 82, 83 are arranged—as already explained in a similar context—between the two first holding sections 5, 6 of the holder 2, or a flat contact surface of the two first holding sections 5, 6 of the holder 2, and a contact surface 61 of a first and a second contact part 55, 56 of an attachment region 54 of the housing section 52 (cf. FIG. 3). Thus, the connection plug 80 can be arranged so as to be movable between the housing 50 and the plug holding device 1.

FIG. 3 shows only the housing 50 from FIG. 2. The housing 50 of the axle device has a housing wall 51 for delimiting an interior of the housing 50 from an exterior of the housing 50 and the housing section 52 for the attachment of a plug holding device 1 for holding the connection plug 80 of the electrical plug connection (cf. FIG. 2).

In this regard, the housing section 52 protrudes from the housing wall 51 towards the interior of the housing 50, wherein the housing section 52 has a connector 53 for correctly attaching the connection plug 80 of the electrical plug connection. In the present case, the connector 53 utilizes the so-called “poka-yoke” principle and is formed accordingly with the connection plug 80.

Furthermore, FIG. 3 shows that the housing section 52 has the attachment region 54 for the plug holding device 1 for holding the connection plug 80 of the electrical plug connection.

The attachment region 54 has the first and the second contact part 55, 56 for the plug holding device 1 for holding the connection plug 80 of the electrical plug connection. The first and second contact parts 55, 56 are spaced apart from one another. This serves to increase mechanical stability and simultaneously save material.

Furthermore, the first contact part 55 has the connector 53, wherein the second contact part 56 has a stop 57 for restricting the movement of the connection plug 80 of the electrical plug connection in the first plane orientation X-Y.

In addition, FIG. 3 shows that the first and second contact parts 55, 56 each have a contact surface 61, 62 that is aligned in the first plane orientation X-Y.

In this regard, the connector 53 and the stop 57 for restricting movement are each arranged on the respective contact surfaces 61, 62.

Furthermore, the attachment region 54, or the first and second contact parts 55, 56 of which is/are geometrically designed in such a way that it/they can be received or surrounded by the plug holding device 1 (cf. FIGS. 4 to 7). This allows for the assembly of different axle devices to be standardized and simplified, as the housing section 52 and the plug holding device 1 can be adapted to one another, akin to the “lock-and-key” principle.

FIG. 3 further shows that the first and second contact parts 55, 56 each have a stop surface 58, 59 for a positioner 3 of the plug holding device 1. Here, the stop surfaces 58, 59 are aligned in a second plane orientation X-Z.

Furthermore, the stop surfaces 58, 59 and the contact surfaces 61, 62 are oriented perpendicular to one another.

FIG. 3 further shows that the housing section 52 has a spacing region 60 for spacing apart the attachment region 54 from the housing wall 51, wherein the housing section 52 is formed integrally or in one piece. This means that the distance of the plug holding device 1 attached to the housing section 52 can be reduced/increased or, generally, adjusted.

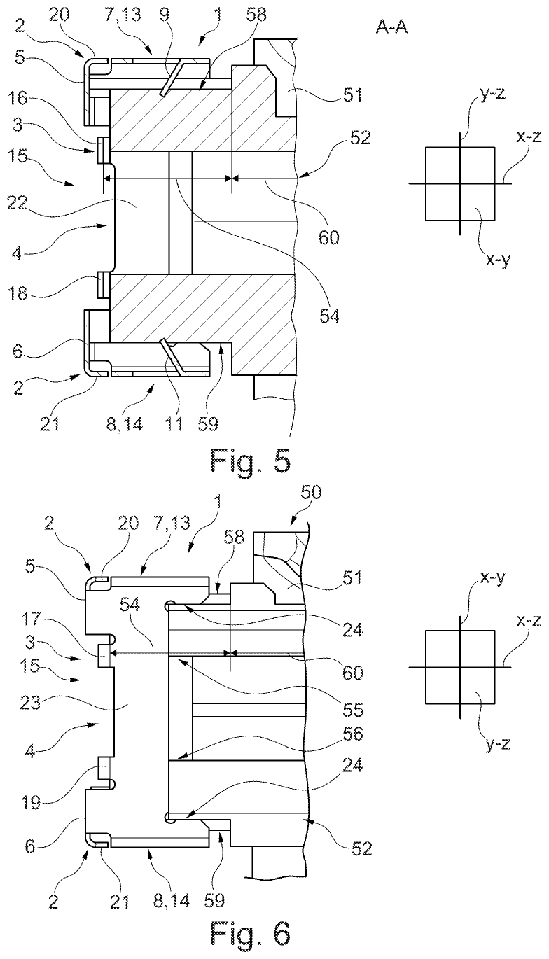

FIG. 4 shows a plan view of the plug holding device 1 on the housing 50 from FIG. 2, wherein FIG. 5 shows a sectional view of the plug holding device 1 on the housing 50 from FIG. 4 along line A-A.

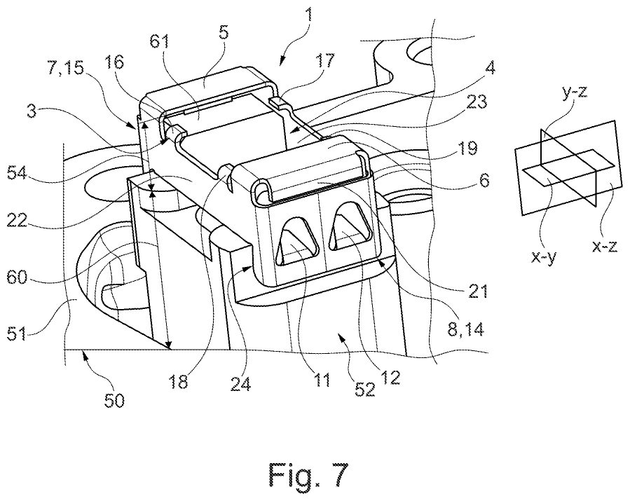

FIG. 6 shows a side view of the plug holding device 1 on the housing 50 from FIG. 4 and FIG. 7 shows a further spatial view of the plug holding device 1 on the housing 50 from FIG. 2.

For the sake of simplicity and brevity, FIGS. 4 to 7 are described together below.

As such, FIGS. 4 to 7 show the plug holding device 1 for holding the connection plug 80 of the electrical plug connection on the housing section 52 of the housing 50 of the axle device.

The plug holding device 1 has the holder 2 configured to hold the plug holding device 1 on the housing section 52 of the housing 50 of the axle device and to hold the connection plug 80 of the electrical plug connection.

Furthermore, the plug holding device 1 has the positioner 3 configured to position the connection plug 80 of the electrical plug connection relative to the plug holding device 1.

The holder 2 has a feed-through 4 configured to receive a male section 81 of the connection plug 80 of the electrical plug connection. This design allows the connection plug 80 of the electrical plug connection to be positioned between the plug holding device 1 and the housing 50 or the housing section 52 of the housing 50.

In addition, FIGS. 4 to 7 show that the holder 2, or the first holding sections 5, 6 of which is/are configured and designed such that the connection plug 80 of the electrical plug connection can be arranged so as to be displaceable on the housing section 52, and can, specifically, be arranged so as to be displaceable in the first plane orientation X-Y (cf. FIG. 2). The displaceability allows for a simple blind assembly, as the connection plug 80 has a range of movement that facilitates insertion into a correspondingly designed socket during blind assembly.

In this regard, the holder 2 thus has the two first holding sections 5, 6, via which the connection plug 80 of the electrical plug connection can be arranged on the housing section 52. The first holding sections 5, 6 at least partially delimit the feed-through 4 or adjoin the feed-through 4. This makes it possible to introduce supporting forces, for example directly or immediately, when the connection plug 80 is plugged into the housing section 52, without another element or component or another device being arranged in between.

In this regard, the first holding sections 5, 6 each have a flat contact surface which can be arranged in contact with the holding region 82, 83 of the connection plug 80 of an electrical plug connection (cf. FIG. 2) in order to ensure that the holding region 82, 83 of the connection plug 80 bears flat against the plug holding device 1. This allows for the distribution of pressure. The first holding sections 5, 6 are aligned in the first plane orientation X-Y.

FIGS. 4 to 7 also show that the holder 2 has two second holding sections 7, 8, via which the plug holding device 1 is fastened to the housing section 52 of the housing 50.

The second holding sections 7, 8 have a total of four securing devices, which are designed as barbs 9, 10, 11, 12 and which make it more difficult to remove the plug holding device 1 from the housing section 52 of the housing 50.

Strictly speaking, every second holding section 7, 8 has two barbs 9, 10, 11, 12 arranged next to one another, wherein each barb 9, 10, 11, 12 is designed as a cantilever, the free end of which is oriented in the direction of the feed-through 4.

Furthermore, two pairs of barbs 9, 10, 11, 12 are arranged opposite or symmetrically with respect to the feed-through 4, wherein the second holding sections 7, 8 are aligned in the second plane orientation X-Z. This improves the hold of the plug holding device 1 on the housing section 52.

According to FIG. 5, the plug holding device 1 is U-shaped or has a U-shape in a cross-section that is aligned in a third plane orientation Y-Z. This shape makes it easier to receive the housing section 52.

In this regard, a first and second leg 13, 14 of the U-shape, which are aligned in the same direction, are each formed by a second holding section 7, 8 of the holder 2.

A third leg 15 of the U-shape, which acts as a connection between the first and second legs 13, 14, is formed by the two first holding sections 5, 6 of the holder 2 and the feed-through 4 between the two first holding sections 5, 6.

According to FIGS. 4 to 7, the positioner 3 has a plurality of first positioning elements 16, 17, 18, 19, via which the relative position of the connection plug 80 of the electrical plug connection to the plug holding device 1 can be predetermined in the first plane orientation X-Y. This means that the movement of the connection plug 80 of the electrical plug connection can be limited relative to the plug holding device 1.

The first positioning elements 16, 17, 18, 19 are arranged on the feed-through 4 or adjoin the feed-through 4, wherein the first positioning elements 16, 17, 18, 19 are arranged on a stiffener 22, 23 of the plug holding device 1 or on a stiffening section of a stiffener 22, 23 of the plug holding device 1.

As shown in more detail, two first positioning elements 16, 17; 18, 19 are arranged opposite and on the feed-through 4 in order to position the connection plug 80 of the electrical plug connection relative to the plug holding device 1.

Furthermore, two first positioning elements 16, 17; 18, 19 are spaced apart from the holder 2 or from the first holding sections 5, 6 of the holder 2.

FIGS. 4 to 7 also show that the positioner 3 has a plurality of second positioning elements 20, 21, via which the relative position of the connection plug 80 of the electrical plug connection to the plug holding device 1 can be predetermined in the first plane orientation X-Y. This means that the movement of the connection plug 80 of the electrical plug connection can be limited relative to the plug holding device 1.

The second positioning elements 20, 21 are arranged at a transition between the first holding section 5; 6 and the second holding section 7; 8 of the holder 2, wherein the second positioning elements 20, 21 are formed integrally or in one piece with the first holding section 5, 6 of the holder 2. In this regard, the second positioning elements 20, 21 are L-shaped (cf. FIGS. 5 and 6).

According to FIGS. 4 to 7, the stiffener 22, 23 connects the first and second holding sections 5, 6; 7, 8 of the holder 2 to one another and mechanically stiffens them.

In this regard, the stiffener 22, 23 has a first and a second stiffening section, which are each designed to be flat. Here, the first and second stiffening sections are aligned in the third plane orientation Y-Z.

As shown in FIGS. 6 and 7, the stiffener 22, 23 or its first and second stiffening section each form a contact nose 24, via which the stiffener 22, 23 bears against stop surfaces 58, 59 of the contact part 55, 56 of the attachment region 54 of the housing section 52.

Furthermore, FIGS. 4 to 7 show that the stiffener 22, 23 or its first and second stiffening section at least partially delimit the feed-through 4 or adjoin the feed-through 4.

Finally, with regard to the plane orientations, it should be mentioned that the first plane orientation X-Y, the second plane orientation Y-Z and the third plane orientation X-Z are aligned perpendicular to one another.

### LIST OF REFERENCE SYMBOLS

1 Plug holding device
2 Holder
3 Positioner
4 Feed-through
5 First holding section
6 First holding section
7 Second holding section
8 Second holding section
9 Securing device-Barb
10 Securing device-Barb
11 Securing device-Barb
12 Securing device-Barb
13 First leg
14 Second leg
15 Third leg
16 First positioning element
17 First positioning element
18 First positioning element
19 First positioning element
20 Second positioning element
21 Second positioning element
22 Stiffener-First stiffening section
23 Stiffener-Second stiffening section
24 Contact nose
50 Housing
51 Housing wall
52 Housing section
53 Connector
54 Attachment region
55 First contact part
56 Second contact part
57 Stop
58 Stop surface
59 Stop surface
60 Spacing region
61 Contact surface
62 Contact surface
80 Connection plug
81 Male section
82 Holding region
83 Holding region
100 Plug holding device
150 Housing
X-Y First plane orientation
Y-Z Second plane orientation
X-Z Third plane orientation

What is claimed is:

1. A plug holding device for holding a connection plug of an electrical plug connection on a housing section of a housing of an axle device, comprising:
a holder configured to hold the plug holding device on the housing section of the housing of the axle device and to hold the connection plug of the electrical plug connection, and
a positioner configured to position the connection plug of the electrical plug connection relative to the plug holding device,
wherein the holder includes a feed-through configured to receive a male section of the connection plug of the electrical plug connection.

2. The plug holding device according to claim 1, wherein the holder is configured such that the connection plug is displaceable on the housing section of the housing of the axle device.

3. The plug holding device according to claim 1,
wherein the holder includes at least one first holding section, via which the connection plug of the electrical plug connection is arranged on the housing section of the housing of the axle device, and
wherein the at least one first holding section at least partially delimits the feed-through or adjoins the feed-through.

4. The plug holding device according to claim 3,
wherein the holder includes at least one second holding section, via which the plug holding device fastened to the housing section of the housing of the axle device, and
wherein the at least one second holding section includes at least one securing device configured to engage the housing section of the housing of the axle device.

5. The plug holding device according to claim 3, wherein the at least one first holding section includes a flat surface arranged to contact a holding region of the connection plug.

6. The plug holding device according to claim 1, wherein the positioner includes at least one positioning element configured to position the connection plug of electrical plug connection relative to the plug holding device in a first plane orientation.

7. The plug holding device according to claim 6,
wherein the at least one positioning element is arranged at a transition between a first and a second holding section of the holder.

8. The plug holding device according to claim 7,
wherein the first holding section is arranged such that a holding region of the connection plug is disposed between the first holding section and the housing section;
wherein the second holding section extends from the first holding section and is configured to engage the housing section.

9. The plug holding device according to claim 6, wherein the at least one positioning element is arranged on the feed-through.

10. The plug holding device according to claim 9, wherein the at least one positioning element adjoins the feed-through.

11. The plug holding device according to claim 6, wherein the at least one positioning element adjoins the feed-through.

12. The plug holding device according to claim 6, wherein the positioner includes at least one further positioning element configured to position the connection plug of electrical plug connection relative to the plug holding device in the first plane orientation;
wherein the at least one positioning element is arranged on the feed-through;
wherein the at least one further positioning element is arranged at a transition between a first and a second holding section of the holder.

13. The plug holding device according to claim 12,
wherein the first holding section is arranged such that a holding region of the connection plug is disposed between the first holding section and the housing section;
wherein the second holding section extends from the first holding section and is configured to engage the housing section.

14. A housing of an axle device, comprising:
a housing wall delimiting an interior of the housing from an exterior of the housing, and
a housing section configured to support a plug holding device for holding a connection plug of an electrical plug connection,
wherein the housing section protrudes from the housing wall towards the interior of the housing, and
wherein the housing section has at least one connector configured to correctly attach the connection plug of the electrical plug connection.

15. The housing according to claim 14,
wherein the housing section includes an attachment region, the attachment region having a first and a second contact part each configured to engage the plug holding device.

16. The housing according to claim 15,
wherein the first and second contact parts are configured to be received in the plug holding device, and
wherein at least one of the first and second contact part includes a stop surface configured to engage a positioner of the plug holding device.

17. The housing according to claim 15, wherein the first and second contact parts are spaced from each other.

18. The housing according to claim 15, wherein the connector is arranged on one of the first contact part or the second contact part.

19. The housing according to claim 15, wherein the first and second contact parts each include a contact surface configured to contact a holding region of the connection plug, the contact surfaces being aligned in a first plane orientation with each other.

20. A system for fastening a connection plug of an electrical plug connection to a housing section of a housing of an axle device, comprising:
a plug holding device for holding the connection plug of the electrical plug connection on the housing section of the housing of the axle device, wherein the plug holding device includes:
a holder configured to hold the plug holding device on the housing section of the housing of the axle device and to hold the connection plug of the electrical plug connection, and
a positioner configured to position the connection plug of the electrical plug connection relative to the plug holding device,
wherein the holder includes a feed-through configured to receive a male section of the connection plug of the electrical plug connection and the housing of the axle device, wherein the housing includes:
a housing wall delimiting an interior of the housing from an exterior of the housing, and
wherein the housing section is configured to support the plug holding,
wherein the housing section protrudes from the housing wall towards the interior of the housing, and
wherein the housing section has at least one connector configured to correctly attach the connection plug of the electrical plug connection.
